(19) United States
(12) Patent Application Publication
(10) Pub. No.: US 2020/0292891 A1
(43) Pub. Date: Sep. 17, 2020

(54) DISPLAY PANEL, MANUFACTURING METHOD THEREOF AND DISPLAY APPARATUS

(71) Applicant: HKC Corporation Limited, Shenzhen (CN)

(72) Inventor: Chunhui YANG, Changqing (CN)

(21) Appl. No.: 16/349,597

(22) PCT Filed: Nov. 29, 2018
(86) PCT No.: PCT/CN2018/118158

§ 371 Date: May 13, 2019

(30) Foreign Application Priority Data
Nov. 12, 2018 (CN) 201811338861.5

(51) Int. Cl. G02F 1/1362; H01L 27/12

(52) U.S. Cl. CPC G02F 1/136209; G02F 1/136286; H01L 27/1259; H01L 27/1244

(57) ABSTRACT

The present application discloses a display panel, a manufacturing method and a display apparatus. The display panel includes: a first substrate; a first metal layer, a first insulating layer and a semiconductor, layer stacked on the first substrate respectively and haying consistent shapes; a second metal layer; and a second insulating layer that covers the stacked first metal layer, the first insulating layer and the semiconductor layer and is formed between the first metal layer and the second metal layer.

The present application claims priority to the Chinese Patent Application No. CN201811338861.5, filed with the Chinese Patent Office on Nov. 12, 2018, and entitled “DISPLAY PANEL MANUFACTURING ME5THOD AND DISPLAY APPARATUS”, which is incorporated herein by reference in its entirety.

### TECHNICAL FIELD

The present application relates to the technical field of display, and in particular, to a display panel, a manufacturing method and a display apparatus.

### BACKGROUND

The description here only provides background information related to the present application, and does not necessarily constitute the existing technology.

The liquid crystal display (LCD) has numerous advantages such as thin body, power saving and no radiation, and is widely applied. Most of the liquid crystal displays on the market are backlight liquid crystal display, including a liquid crystal panel and a backlight module. A manufacture procedure of a thin film transistor-liquid crystal display (TFT-LCD) includes array engineering, color film engineering and liquid crystal box manufacturing engineering. The array engineering includes cleaning technique, CVD technique, sputter film technique, photoresist covering, developing and stripping teclmique, exposure technique, etching technique, dry etching technique, and so on. Finally, four to five film patterns are formed on a surface of the glass substrate.

The four exemplary processes (for short, 4 masks) include: first metal layer engineering (for short, G engineering) and protective layer engineering (for short, I engineering), second metal layer engineering (for short, D engineering), passivation layer engineering (for short, C engineering), and transparent conductive film engineering (for short, PT engineering). The switch structure formed by the exemplary four processes presents a problem of communication short circuit.

### SUMMARY

This application provides a display panel, a manufacturing method and a display apparatus which can prevent short circuit of a switch structure inside the display panel.

A display panel includes: a first substrate; a first metal layer, a first insulating layer and a semiconductor layer stacked on the first substrate respectively and having consistent shapes; a second metal layer; and a second insulating layer that covers the stacked first metal layer, the first insulating layer and the semiconductor layer and is formed between the first metal layer and the second metal layer.

Optionally, the second insulating layer is a black color resistance.

Optionally, the second insulating layer is made of an insulating material.

Optionally, the first metal layer is a grid electrode; the second metal layer includes a source electrode and a drain electrode that are separated from each other; the first insulating layer is a grid electrode insulating layer; the grid electrode is formed on the first substrate; the grid electrode insulating layer is fomied on the grid electrode; the semiconductor layer is formed on the grid electrode insulating layer; the second insulating layer is formed on the semiconductor layer; a part of the second insulating layer covers the semiconductor layer, and a part does not cover the semiconductor layer; and the source electrode and the drain electrode are disposed in an area of the semiconductor layer that is not covered by the second insulating layer.

Optionally, the second insulating layer is formed with an opening to expose the semiconductor layer; the opening is formed in a non-edge area of the second insulating layer; and the source electrode and the drain electrode are communicated with the semiconductor layer through the opening

Optionally, a distance from the periphery of the opening to an edge of the second insulating layer is greater than 0; and a distance from the opening to an edge of the grid electrode is greater than 0.

Optionally, a length of the source electrode is d5, a length of the drain electrode is d6, a length of the opening is d7, and the length d1 of the source electrode and the length d6 of the drain electrode are equal to the length d7 of the opening.

Optionally, the first metal layer is a scan line; the second metal layer is a data line; and the second insulating layer is disposed at the intersected and overlapped part of the scan line and the data line.

Optionally, the first substrate is a glass substrate.

Optionally, the first metal layer is a grid electrode; and the second metal layer includes the source electrode and the drain electrode independent of each other.

Optionally, the first insulating layer and the semiconductor layer are formed by exposure and development of the same mask and have consistent shapes.

The present application also, discloses a manufacturing method of a display panel including steps of:

providing a first substrate, covering a first metal laver, a first insulating layer and a semiconductor layer, and forming the first metal layer, the first insulating layer and the semiconductor layer with consistent shapes through one-time exposure, development and etching;

forming a second insulating layer that covers the stacked first metal ayer, the first insulating layer and the semiconductor layer:

forming a second metal layer on the second insulating layer that is formed between the first metal layer and the second metal, layer.;

Optionally, after the step of depositing the second metal layer and forming the second metal layer through exposure, development and etching, it further includes steps of:

forming a passivation layer on the second metal layer, and forming a through hole on the passivation layer; and

forming a transparent conductive layer connected with the second metal layer through the through hole;

Optionally, in the step of forming the second insulating layer, the second insulating layer is formed with an opening to expose the semiconductor layer; the opening is formed in a non-edge area of the second insulating layer; and the source electrode and the drain electrode are communicated with the semiconductor layer through the opening.

The present application also discloses a display apparatus including a display panel; the display panel includes: a first substrate; a first metal layer, a first insulating layer and a semiconductor layer stacked on the first substrate respectively and having consistent shapes; a second metal layer; and a second insulating layer that covers the stacked first metal layer, the first insulating layer and the semiconductor layer and is formed between the first metal layer and the second metal layer.

Compared with the display panel whose first metal layer, first insulating layer and semiconductor layer are formed using the same mask manufacture procedure, the first metal layer, the first insulating layer and the semiconductor layer in the present application are formed by exposure and development of the same mask and have consistent shapes; in this way, a corresponding manufacture procedure step may be reduced, and the manufacture cost is saved; however, the edges of the first metal layer, the first insulating layer and the semiconductor layer are aligned, and the bottom part of the first metal layer is exposed, so that short circuit with other conductive components may be easily caused in the subsequent manufacture procedure, and even the display panel will he burnt up; in this scheme, isolating insulation between the first metal layer and the second metal layer is realized through the second insulating layer, and the second insulating layer covers the stacked first metal layer, the first insulating layer and the semiconductor layer, thereby guaranteeing normal display of the display panel.

### BRIEF DESCRIPTION OF DRAWINGS

The drawings are included to provide specific understanding of embodiments of the present application, which constitute a part of the specification and illustrate the embodiments of the present application, and describe the principles of the present application together with the text description. Apparently, the accompanying drawings in the following description show merely some embodiments of the present application, and a person of ordinary skill in the art may still derive other accompanying drawings from these accompanying drawings without creative efforts. In the accompanying drawings:

FIG. 1 is a schematic diagram of a display panel manufacture procedure of one embodiment in the present application;

FIG. 2 is a structural schematic diagram of a display panel of one embodiment in the present application;

FIG. 3 is a structural schematic diagram of a second insulating layer of one embodiment in the present application;

FIG. 4 is a schematic diagram of comparison between a grid electrode and a semiconductor layer of one embodiment in the present applicatin;

FIG. 5 is a schematic diagram of a first metal layer, a semiconductor layer and a second insulating layer of one enibodiment in the present application;

FIG. 6 is a structural schematic diagram of a data line, a source electrode and a drain electrode of one embodiment in the present application;

FIG. 7 is a structural schematic diagram of the source electrode, the dram electrode and an opening of one embodiment in the present application;

FIG. 8 is a structural schematic diagram of a data line and a scan line another embodiment in the present application;

FIG. 9 is a schematic diagram of an intersected and overlapped area of the data line and the scan line of another embodiment in the present application;

FIG. 10 is a flow diagram of a manufacturing, method of the display panel of another embodiment in the present application; and

FIG. 11 is a structural schematic diagram of a display apparatus of another embodiment in the present application.

### DETAILED DESCRIPTION

It should be understood that, the terms used herein, the disclosed specific structure and function details are merely intended to describe specific embodiments and are representative. However, the present application can be specifically embodied in many alternative forms, and should not be interpreted to he limited to the embodiments described herein.

In description of the present application, the terms such as “first” and “second” are merely for a descriptive purpose, and cannot be understood as indicating or implying relative importance, or implicitly indicating the number of the indicated technical features. :Hence, the features defined by “first” and “second” can explicitly or implicitly include one or more features; “a plurality of” means two or more, unless otherwise stated. The term “include” and any variatiom thereof are intended to cover a non-exclusive inclusion; there may be the presence or addition of one or more other features, integers, steps, operations, elements, components and/or combinations thereof.

In addition, orientation or position relationships indicated by the terms “center”, “transversal”, “upper”, “lower”, “left”, “right”, “vertical”, “horizontal”, “top”, “bottom”, “inner”, “outer”, etc. are based on the orientation or relative position relationships as shown in the drawings, for ease of the description of the present application and simplifying the description only, rather than indicating that the indicated device or element must have a particular orientation or be, constructed and operated in a particular orientation. Therefore, these terms should not be understood as a limitation to the present application.

In addition, unless otherwise specified and defined, the terms “install”, “connected with”, “connected to” should be comprehended in a broad sense. For example, these terms may be comprehended as being fixedly connected, detachably connected or integrally connected; mechanically connected or electrically connected; or directly connected or indirectly connected through an intermediate medium, or in an internal communication between two elements. The specific meanings about the foregoing tennis in the present application may be understood by those skilled in the art according to specific circumstances.

The present application is illustrated below in detail in reference with the drawings and optional embodiments.

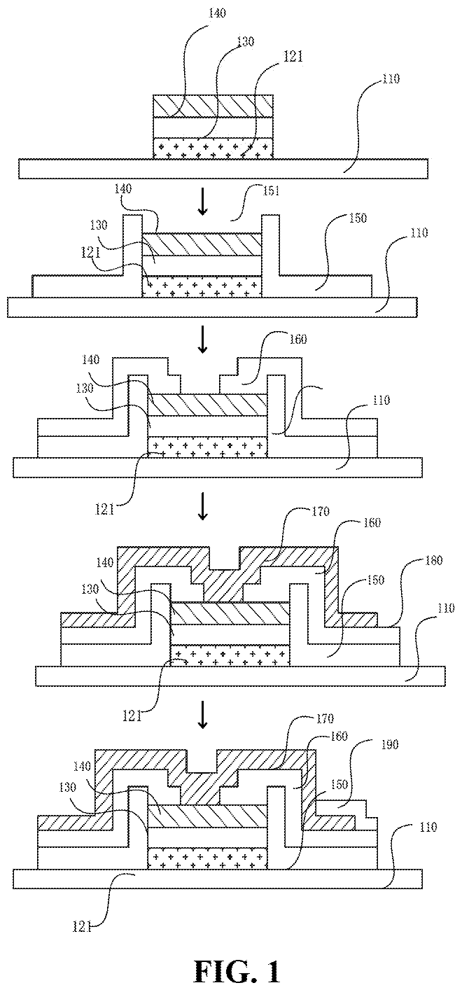

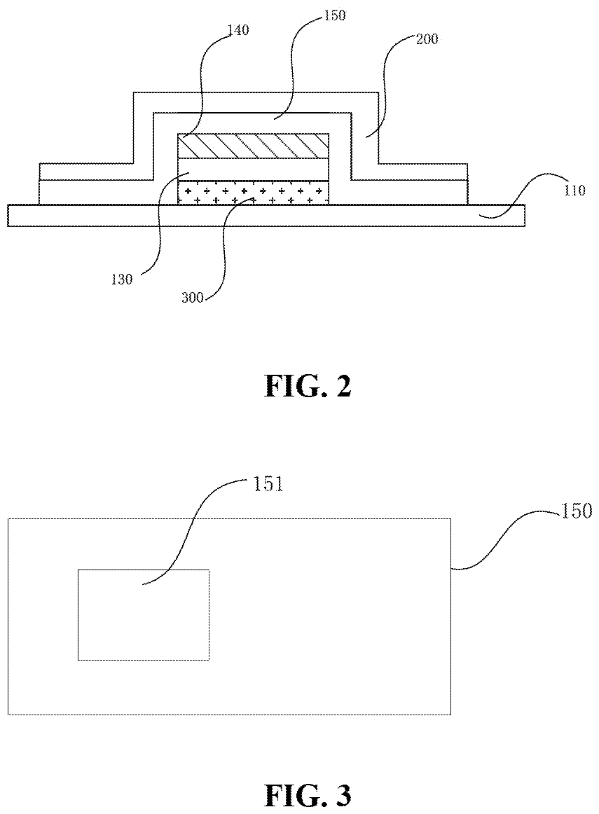

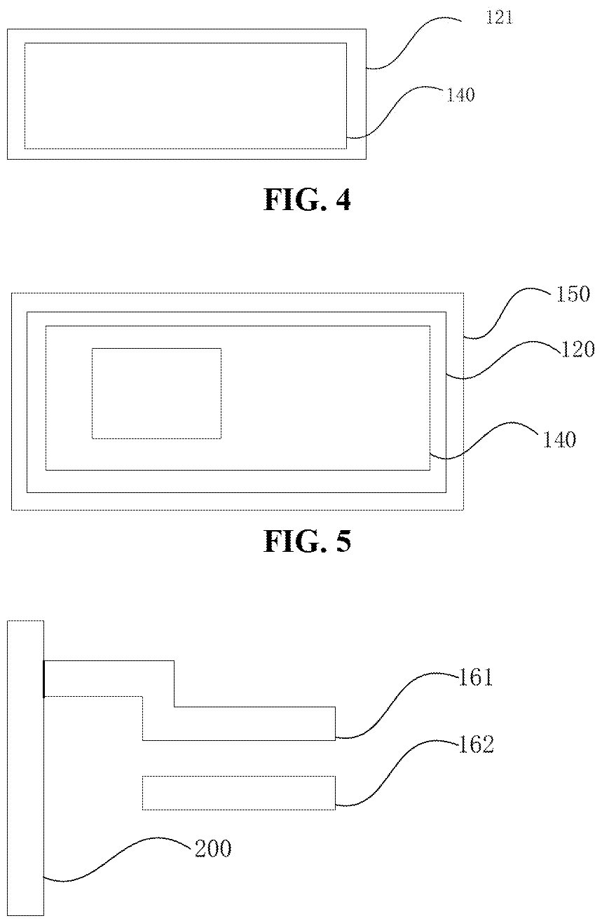

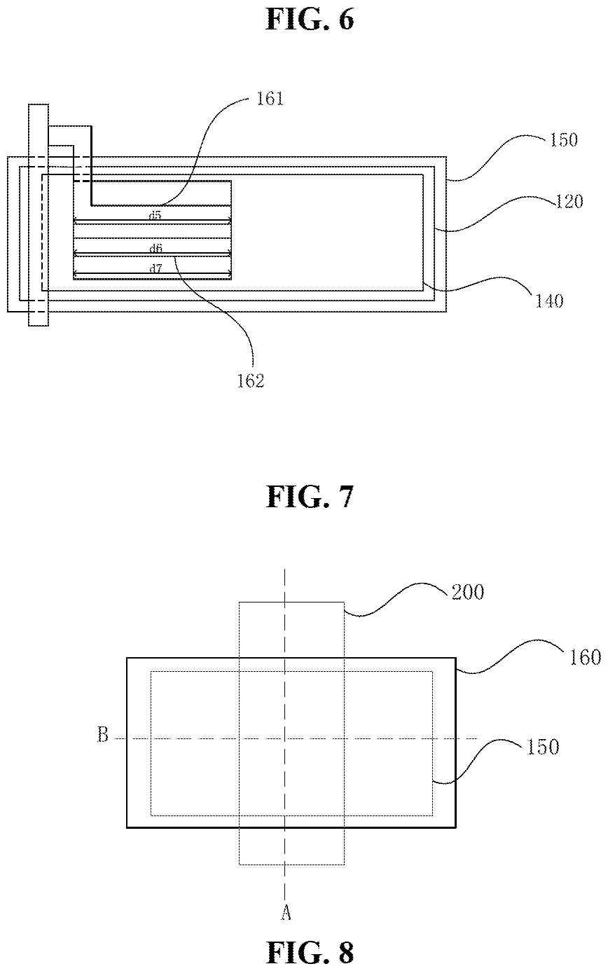

As shown in FIGS. 1 to 11, an embodiment of the present application discloses a display panel 100, a manuficturing method and a display apparatus 10.

A display panel 100 includes: a first substrate 110, a first metal layer 120, a first insulating layer 130 and a semiconductor layer 140, where the first metal layer 120, the first insulating layer 130 and the semiconductor layer 140 are stacked on the first substrate 110, respectively. The first metal layer 120, the first insulating layer 130 and the semiconductor layer 140 have consistent shapes; a second metal layer 160; and a second insulating layer 150 that covers the stacked first metal layer 120, the first insulating layer 130 and the semiconductor layer 140 and is formed between the first metal layer 120 and the second metal layer 160.

Compared with the display panel 100 whose first metal layer 120, first insulating layer 130 and semiconductor layer 140 are formed using the same mask manufacture procedure, the first metal layer 120, the first insulating layer 130 and the semiconductor layer 140 in the this scheme are formed by exposure and development of the same mask and have consistent shapes; in this way, a corresponding manufacture procedure step may be reduced, and the manufacture cost is saved; however, the edges of the first metal layer 120, the first insulating layer 130 and the semiconductor layer 140 are aligned, and the bottom part of the first metal layer 120 is exposed, so that short circuit with other conductive components may be easily caused in the subsequent manufacture procedure, and even the display panel 100 will be burnt up; in this scheme, isolating insulation between the first metal layer 120 and the second metal layer 160 is realized through the second insulating layer 150, and the second insulating layer 150 covers the stacked first metal layer 120, the first insulating layer 130 and the semiconductor layer 140, thereby guaranteeing normal display of the display panel 100.

In addition, the first substrate 110 may be a glass substrate.

In one and more embodiments, the second insulating layer 150 is a black color resistance.

In this scheme, since the first metal layer 120, the first insulating layer 130 and the semiconductor layer 140 have consistent shapes, when the backlight source of the first metal layer 120 enters, the incoming light source may enter the semiconductor layer 140, so that the semiconductor layer 140 generates a current, thereby affecting performance of the display panel 100; the second insulating layer 150 in this scheme is made of a black color resistance, which can efficiently shield light incoming from the backlight source, prevent the light from incoming into the semiconductor layer 140, avoid the semiconductor layer 140 generating a current under the impact of lighting, and improve the performance of the display panel 100. Certainly, the second insulating layer 150 may also use other insulating layer material, as long as the material can realize insulation between the first metal layer 120 and the second metal layer 160.

In one and more embodiments, referring to FIGS. 1, 3, 4 and 5, since the first metal layer, the semiconductor layer and the first insulating layer are made of the same mask, the three have inconsistent shapes for distinguishing and for facilitating observation and understanding. The first metal layer 120 is a grid electrode 121; the second metal layer 160 includes a source electrode 161 and a drain electrode 162 that are separated from each other; and the first insulating layer 130 is a grid electrode 121 insulating layer;

The grid electrode 121 is formed on the first substrate 110; the grid electrode 121 insulating layer is formed on the grid electrode 121; the semiconductor layer 140 is formed on the grid electrode 121 insulating layer; and the second insulating layer 150 is formed on the semiconductor layer 140;

A part of the second insulating layer 150 covers the semiconductor layer 140, and a part does not cover the semiconductor layer 140; and the source electrode 161 and the drain electrode 162 are disposed in the area of the semiconductor layer 140 that is not covered by the second insulating layer 150.

This scheme forms a switch structure, e.g., a thin film transistor (TFT), to improve the performance of the thin film transistor. The first metal layer 120 forms the grid electrode 121 of the thin film transistor; the second metal layer 160 forms die source electrode 161 and the drain electrode 162 of the thin film transistor; the first insulating layer 130 is the grid electrode 121 insulating layer of the thin film transistor; the second insulating layer 150 is formed on the semiconductor layer 140; a part of the second insulating layer 150 covers the semiconductor layer 140, and a part does not cover the semiconductor layer 140; the source electrode 161 and the drain electrode 162 are disposed in an area of the semiconductor layer 140 that is not covered by the second insulating layer 150, so that the source electrode 161 and the drain electrode 162 can be connected with the semiconductor layer 140 in a contact manner; therefore, it guarantees the switch structure formed by the grid electrode 121, the source electrode 161 and the drain electrode 162 may work normally after completing the panel manufacture procedure. If the second insulating layer 150 completely covers the semiconductor layer 140, the grid electrode 121 insulating layer and the second insulating layer 150 exist between the grid electrode 121, the source electrode 161 and the drain electrode 162 and both have a certain thickness, so that the grid electrode 121. the source electrode 161 and the drain electrode 162 cannot work normally, thereby affecting the performance of the display panel 100.

In one and more embodiments, referring to FIG. 5, the second insulating layer 150 is formed with an opening 151 to expose die semiconductor layer 140; the opening 151 is formed in a non-edge area of the second insulating layer 150; and the source electrode 161 and the drain electrode 162 are communicated with the semiconductor layer 140 through the opening 151.

In this scheme, the second insulating layer 150 is provided with an opening 151; the opening 151 is disposed in an area other than the edge part of the second insulating layer 150; since the semiconductor layer 140 and the grid electrode 121 have consistent shapes, the backlight source on one side of the grid electrode 121 may enter the semiconductor layer 140 to cause the semiconductor layer 140 to generate a current, so that light leakage or non-uniform display will occur to the display panel 100. When the opening 151 is disposed in the non-edge area of the second insulating layer 150, a distance from the periphery of the opening 151 to the edge of the second insulating layer 150 is greater than 0; a distance from the opening 151 to the edge of the grid electrode 121 is greater than 0; the non-opening 151 area of the second insulating layer 150 can shield the light incoming from the backlight source, so as to prevent the semiconductor layer 140 from generating a light current and avoid light leakage or non-uniform display brightness of the display panel 100.

Optionally, in this embodiment, referring to FIG. 7, a length of the source 161 is d5; a length of the drain electrode 162 is d6; a length of the opening 151 is d7; and the length d5 of the source electrode 161 and the length d6 of the drain electrode 162 are equal to the length d7 of the opening 151.

In this scheme, the length d5 of the source electrode 161 and the length d6 of the drain electrode 162 are equal to the length d7 of the opening 151, so that the source electrode 161 and the drain electrode 162 can shield the semiconductor layer 140 to prevent radiation from the external light source.

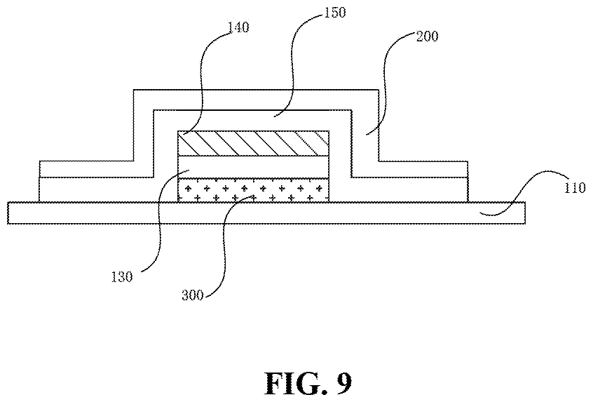

Optionally, in one and more embodiments, referring to FIGS. 8 and 9, the first metal layer 120 is a scan line 300; the second metal layer 160 is a data line 200; and the second insulating layer 150 is disposed at the intersected and overlapped part of the scan line 300 and the data line 200.

This scheme is mainly directed to the intersected and overlapped part of the data line 200 and the scan line 300; due to the manufacture procedure precision of the display panel 100, the data line 200 and the scan line 300 may be communicated; and if the second insulating layer 150 is not disposed in the intersected and overlapped area of the scan line 300 and the data line 200, short circuit may occur in the display panel 100 to burn up the display panel 100. After disposing the second insulating layer 150, the second insulating layer 150 corresponds to the intersected and overlapped area of the data line 200 and the scan line 300. which may prevent short circuit caused by communication of the data line 200 and the scan line 300 and guarantee normal display of the display panel 100.

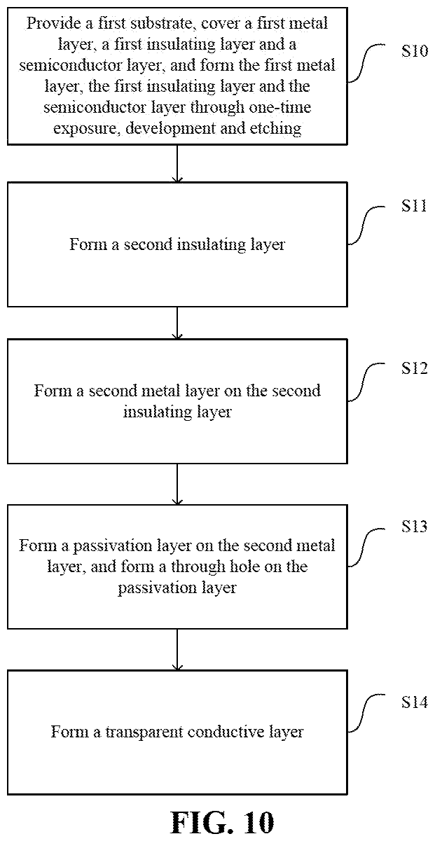

As shown in FIG. 10, in one and more embodiments, it discloses a manufacturing method of the display panel 100, including the following steps:

S10: providing a first substrate 110, covering a first metal layer 120, a first insulating layer 130 and a semiconductor layer 140, and form the first metal layer 120, the first insulating layer 130 and the semiconductor layer 140 with consistent shapes through one-time exposure, developnient and etching;

S11: forming a second insulating layer 150 that covers the stacked first metal layer 120, the first insulating layer 130 and the semiconductor layer 140;

S12: forming a second metal layer 160 on the second insulating layer 150 that is formed between the first metal layer 120 and the second metal layer 160;

In this scheme, the first metal layer 120, the first insulating layer 130 and the semiconductor layer 140 have consistent shapes; the three layers can be manufactured by the same mask, so that the corresponding manufacture procedure step can be reduced, and the manufacture cost is saved; however, the subsequent manufacture procedure requires to dispose the second metal layer 160, if the first metal layer 120 and the second metal layer 160 are not isolated, the first metal layer 120 and the second metal layer 160 may be communicated after completing all the manufacture procedures, thereby causing short circuit and even burning up the display panel 100. The second insulating layer 150 is disposed between the first metal layer 120 and the second metal layer 160, so that isolating insulation between the first metal layer 120 and the second metal layer 160 is realized, thereby guaranteeing normal display of the display panel 100.

In addition, the first substrate 110 may be a glass substrate, and other suitable materials may also be used.

Optionally, in one or more embodiments, after the step of depositing the second metal layer 160 and forming the second metal layer 160 through exposure, development and etching, it further includes the following steps:

S13: forming a passivation layer 170 on the second metal layer 100, and form a through hole 180 on the passivation layer 170;

S14: forming a transparent conductive layer 190 connected with the second metal layer 160 through the through hole 180;

This scheme forms a switch structure, e.g., a thin film transistor(TFT); the first metal layer 120 forms a grid electrode 121; the second insulating layer 150 forms a grid electrode 121 insulating layer: the second metal layer includes the source electrode 161 and the drain electrode 162 that are separated from each other; the source electrode 161 and the drain electrode 162 form the passivation layer 170, form the through hole 180 on the passivation layer 170, and finally form a transparent electrode layer, and thus a complete switch structure is formed; since the grid electrode 121, the first insulating layer 130 and the semiconductor of the switch structure are formed by a mask; the first insulating layer 130 covers the grid electrode 121 incompletely; a part of the grid electrode 121 is exposed: when the source electrode 161 and the drain electrode 162 are formed, the grid electrode 121 may be communicated with the source electrode 161 and the drain electrode 162, thereby causing short circuit and even burning up the panel; therefore, the second insulating layer 150 is disposed between the grid electrode 121 and the source electrode 161 as well as the drain electrode 162, and thus isolating insulation treatment is performed between the grid electrode 121 and the source electrode 161 as well as the drain electrode 162, thereby causing the display panel 100 to work normally and guaranteeing the performance of the display panel.

This scheme can certainly form the data line 200 and the scan line 300; the first metal layer 120 forms the scan line 300; the second nietal layer 160 forms the data line 200; due to the manufacture procedure precision of the display panel 100, the data line 200 and the scan line 300 may be communicated; and if the second insulating layer 150 is not disposed in the intersected and overlapped area of the scan line 300 and the data line 200, short circuit may occur in the display panel 100 to burn up the display panel 100. After disposing the second insulating layer 150, the second insulating layer 150 corresponds to the intersected and overlapped area of the data line 200 and the scan line 300, which may prevent short circuit caused by communication of the data line 200 and the scan line 300 and guarantee normal display of the display panel 100.

Certainly, other switch structures may also be applicable.

In one and more embodiments, in the step of forming the second insulating layer 150, the second insulating layer 150 is formed with the opening 151 to expose the semiconductor layer 140; the opening 151 is formed in the non-edge area of the second insulating layer 150; and the source electrode 161 and the drain electrode 162 are communicated with the semiconductor layer 140 through the opening 151.

In this scheme, for the opening 151 of the second insulating layer 150, it only requires to dispose a shading pattern corresponding to the opening 151 on a mask used in an exposure process to form the opening 151 after corresponding development; and the manufacture procedure of the second insulating layer 150 does not add any process step and is simple and practicable.

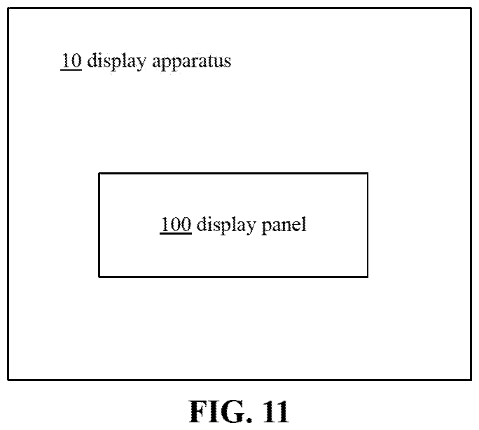

As shown in FIG. 11, as another embodiment of the present application, it discloses a display apparatus 10 including the above-mentioned display panel 100.

In this scheme, in the switch structure in the display panel, the first metal layer 120 and the second metal layer 160 are isolated through the second insulating layer 150, and the second insulating layer 150 covers the stacked first metal layer 120, the first insulating layer 130 and the semiconductor layer 140, thereby guaranteeing normal display of the display panel 100.

Certainly, the first metal layer 120 may be the source electrode 121 or the scan line 200, and the second metal insulating 160 may be the source electrode 161 and the drain electrode 162 and may also be the data line 300.

It should be noted that, definition of various steps involved in this scheme is not deemed as definition to the order of the steps without affecting the specific scheme implementation; the steps mentioned first may be performed first or last, and may even be performed simultaneously; and as long as the steps can implement this scheme, they should be deemed as belonging to the protection scope of the present application.

The technical scheme of the present application may be widely applied to various display panels, e.g., a TN type display panel (full name is Twisted Nematic, i.e., twisted nematic panel), an IPS type display panel (In-Plane Switching), a VA type display panel (Vertical Alignment, vertical alignment technology), and an MVA type display panel (Multi-Domain Vertical Alignment, Multi-Domain vertical alignment technology), and certainly may also be other types of display panels, e.g., an organic light-emitting display panel (organic light-emitting diode, for short an OLED display panel), which may be suitable for the above-mentioned scheme.

The above contents are detailed optional descriptions for the present application in conjunction with the specific optional implementation, and it cannot be affirmed that the specific implementation of the present application is only limited to these descriptions. For those skilled in the art of the present application, several simple deductions or replacements can further be made without departing from the idea of the present application and should be deemed as belonging to the scope of protection of the present application.

What is claimed is:

1. A display panel, comprising:
a first substrate;
a first metal layer, a first insulating layer and a semiconductor layer stacked on the first substrate respectively and having consistent shapes;
a second metal layer; and
a second insulating layer that covers the stacked first metal layer, the first insulating layer and the semiconductor layer and is formed between the first metal layer and the second metal layer.

2. The display panel according to claim 1, wherein, the second insulating layer is a black color resistance.

3. The display panel according to claim 2, wherein, the second insulating layer is made of an insulating material.

4. The display panel according to claim 1, wherein, the first metal layer is a grid electrode, the second metal layer comprises a source electrode and a drain electrode that are separated from each other, and the first insulating layer is a grid electrode insulating layer;
the grid electrode is formed on the first substrate, the grid electrode insulating layer is formed on the grid electrode, the semiconductor layer is formed on the grid electrode insulating layer, and the second insulating layer is formed on the semiconductor layer; and
a part of the second insulating layer covers the semiconductor layer, and a part does not cover the semiconductor layer; and the source electrode and the drain electrode are disposed in an area of the semiconductor layer that is not covered by the second insulating layer.

5. The display panel according to claim 3, wherein, the second insulating layer is formed with an opening to expose the semiconductor layer; the opening is formed in a non-edge area of the second insulating layer; and the source electrode and the drain electrode are communicated with the semiconductor layer through the opening.

6. The display panel according to claim 3, wherein, a distance from the periphery of the opening to an edge of the second insulating layer is greater than 0; and a distance front the opening to an edge of the grid electrode is greater than 0.

7. The display panel according to claim 4, wherein, a length of the source electrode is d5; a length of the drain electrode is d6; a length of the opening is d7; and the length d5 of the source electrode and the length d6 of the drain electrode are equal to the length d7 of the opening.

8. The display panel according to claim wherein, the first metal layer is a scan line; the second metal line is a data line; and the second insulating layer is disposed at the intersected and overlapped part of the scan line and the data line.

9. The display panel according to claim 1, wherein, the first substrate is a glass substrate.

11. The display panel according to claim 1, wherein, the first metal layer is a grid electrode; and the second metal layer comprises the source electrode and the drain electrode independent of each other.

12. The display panel according to claim 1, wherein, the first metal layer, the first insulating layer and the semiconductor layer are formed by exposure and development of the same mask and have consistent shapes.

13. A manufacturing method of a display panel, comprising steps of:
providing a first substrate, covering a first metal layer, a first insulating layer and a semiconductor layer, and forming the first metal layer, the first insulating layer and the semiconductor layer with consistent shapes through one-time exposure, development and etching;
formiing a second insulating layer that covers the stacked first metal layer, the first insulating layer and the semiconductor layer; and
forming a second metal layer on the second insulating layer that is formed between the first metal layer and the second metal layer.

14. The manufacturing method of a display panel according to claim 13, wherein, after the step of depositing the second metal layer and forming the second metal layer through exposure, development and etching, it further comprises steps of:
forming a passivation layer on the second metal layer, and forming a through hole on the passivation layer.

15. The manufacturing method of a display panel according to claim 14, wherein, after forming the passivation layer on the second metal layer and forming the through hole on the passivation layer, it further comprises a step of:
forming a transparent conductive layer connected with the second metal layer through the through hole.

16. The manufacturing, method of a display panel according to claim 13, wherein, in the step of forming the second insulating layer, the second insulating layer is formed with an opening to expose the semiconductor layer; the opening is formed in a non-edge area of the second insulating layer; and the source electrode and the drain electrode are communicated with the semiconductor layer through the opening.

17. The manufacturing method of a display panel according to claim 16, wherein, a distance from the periphery of the formed opening to an edge of the second insulating layer is greater than 0; and a distance from the opening to an edge of the grid electrode is greater than 0.

18. A display apparatus, comprising a display panel that comprises: a first substrate;
a first metal layer, a first insulating layer and a semiconductor layer stacked on the first substrate respectively and having consistent shapes;
a second metal layer; and
a second insulating layer that covers the stacked first metal layer, the first insulating layer and the semiconductor layer and is formed between the first metal layer and the second metal layer.
